(19) United States
(12) Patent Application Publication
(10) Pub. No.: US 2025/0324661 A1
(43) Pub. Date: Oct. 16, 2025

(54) SEMICONDUCTOR DEVICE

(71) Applicant: ROHM CO., LTD., Kyoto (JP)

(72) Inventors: Yasushi HAMAZAWA, Kyoto (JP); Takeshi ISHIDA, Kyoto (JP)

(73) Assignee: ROHM CO., LTD., Kyoto (JP)

(21) Appl. No.: 19/176,426

(22) Filed: Apr. 11, 2025

(30) Foreign Application Priority Data
Apr. 12, 2024 (JP) 2024-064631

(51) Int. Cl. H10D 30/66; H10D 62/17; H10D 64/27

(52) U.S. Cl. CPC H10D 30/668; H10D 62/393; H10D 64/513

(57) ABSTRACT

A semiconductor device includes a semiconductor substrate of a first conductivity type, and a semiconductor layer of the first conductivity type. The semiconductor layer includes a trench gate, a source region of the first conductivity type, a contact region of a second conductivity type and a column region of the second conductivity type. The semiconductor layer has formed therein a plurality of trench gates arranged at certain intervals along a first direction and a second direction, respectively. The source region is in contact with the trench gate and surrounds the trench gate. The contact region is disposed between source regions adjacent to each other along the second direction, and the column region extends toward the semiconductor substrate from one end of the contact region that is closer to the semiconductor substrate.

### CROSS REFERENCE TO RELATED APPLICATION

This application is based upon and claims the benefit of priority of the prior Japanese Patent Application No. 2024-064631, filed on Apr. 12, 2024, the entire contents of which are incorporated herein by reference.

### TECHNICAL FIELD

The present disclosure relates to a semiconductor device.

### BACKGROUND ART

Japanese Patent Application Laid-open Publication No. 2014-222710 (Patent Document 1) discloses, as a semiconductor device, an n-channel MOSFET (metal oxide semiconductor field effect transistor) that has the super-junction structure. The cell structure of an embodiment of the semiconductor device disclosed in Patent Document 1 is the trench-gate structure. Japanese Patent Application Laid-open Publication No. 2013-115385 discloses, a semiconductor device including a trench gate MISFET (metal insulator semiconductor field effect transistor) in which super-junction is formed.

### BRIEF DESCRIPTION OF THE DRAWINGS

FIG. 1 is a plan view of an example of a semiconductor device of Embodiment 1.

FIG. 2 is a diagram illustrating the internal structure of the semiconductor device of FIG. 1.

FIG. 3 is a schematic view illustrating an example of the cross-sectional structure along the line III-III of FIG. 2.

FIG. 4 is a schematic view illustrating an example of the cross-sectional structure along the line IV-IV of FIG. 2.

FIG. 5 is a schematic view illustrating an example of the cross-sectional structure along the line V-V of FIG. 2.

FIG. 6 is a diagram illustrating an example of the structure on a primary surface of an epitaxial layer (semiconductor layer) in the semiconductor device of Embodiment 1.

FIG. 7 is a plan view of the epitaxial layer (semiconductor layer), viewed from the VII-VII line of FIG. 6.

FIG. 8 is a plan view of the epitaxial layer (semiconductor layer), viewed from the VIII-VIII line of FIG. 6.

FIG. 9 is a plan view of an example of a semiconductor device of Embodiment 2.

FIG. 10 is a diagram illustrating another example of the structure on the primary surface of the epitaxial layer (semiconductor layer) in the semiconductor device.

FIG. 11 is a plan view of the epitaxial layer (semiconductor layer), viewed from the XI-XI line of FIG. 10.

### DETAILED DESCRIPTION OF EMBODIMENTS

Below, embodiments of the present disclosure will be explained with reference to the figures. In each figure, the same or corresponding components are given the same reference character and the descriptions thereof will not be repeated. The size proportions of the figures do not necessarily align with those of the descriptions.

### Embodiment 1

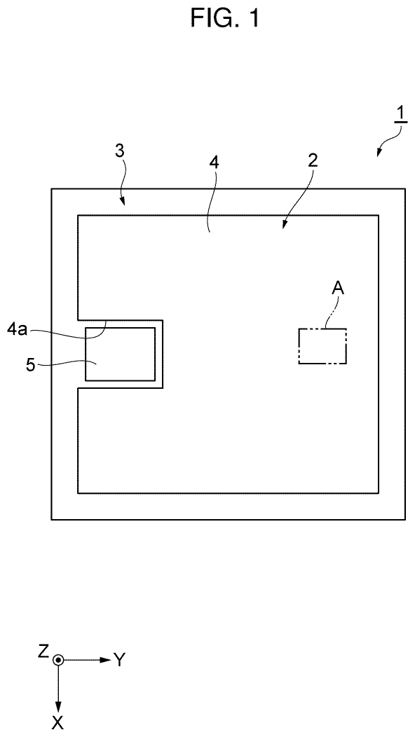

FIG. 1 is a plan view of a semiconductor device of Embodiment 1. A semiconductor device 1 includes a MISFET (metal insulator semiconductor field effect transistor). The description below discusses a case where the semiconductor device 1 includes a MOSFET (metal oxide semiconductor field effect transistor), which is a type of MISFET.

The semiconductor device 1 is a semiconductor switching device, for example. The outer shape of the semiconductor device 1 is an approximately square chip shape in a plan view, as illustrated in FIG. 1, for example. The dimensions of the chip-shaped semiconductor device 1 are approximately several mm in the thickness direction and in the two directions intersecting therewith. The shape of the semiconductor device 1 is not limited to the shape illustrated in the figure.

The semiconductor device 1 includes an active region 2 and a surrounding region 3 that surrounds the active region 2. The active region 2 is located in the center of the semiconductor device 1 in a plan view, for example. A guard ring may be formed in the surrounding region 3.

On the surface of the semiconductor device 1, a source pad 4 is formed. The source pad 4 is formed to cover the surface of the semiconductor device 1 almost entirely. In this embodiment, the source pad 4 is formed in the active region 2. The source pad 4 has an approximately square shape in a plan view with each corner curving outward. In the approximate middle of one of the sides of the source pad, a recess 4a is formed. The recess 4a is an area where the source pad 4 is not formed. The source pad 4 may be formed of aluminum or other metals.

A gate pad 5 is disposed in the recess 4a. The gate pad 5 may be formed of aluminum or other metals. The gate pad 5 and the source pad 4 have a gap therebetween and are electrically insulated from each other.

Examples of the semiconductor materials constituting the semiconductor device 1 include silicon (Si), compound semiconductor, and the like. The compound semiconductor may be a III-V compound semiconductor, IV-IV compound semiconductor, and an alloy semiconductor using these semiconductors. For the III-V compound semiconductor, Ga semiconductors such as gallium arsenide (GaAs) or gallium nitride (GaN) may be used. For the IV-IV compound semiconductor, Si semiconductors such as silicon carbide (SiC) or silicon-germanium (SiGe) may be used.

N-type impurities used for the semiconductor device 1 include P (phosphate), As (arsenal), and SB (antimony), and P-type impurities include B (boron), Al (aluminum), and Ga (Gallium).

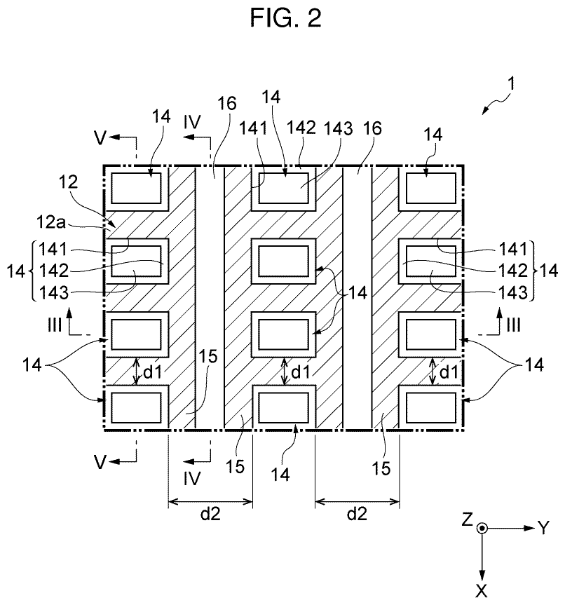

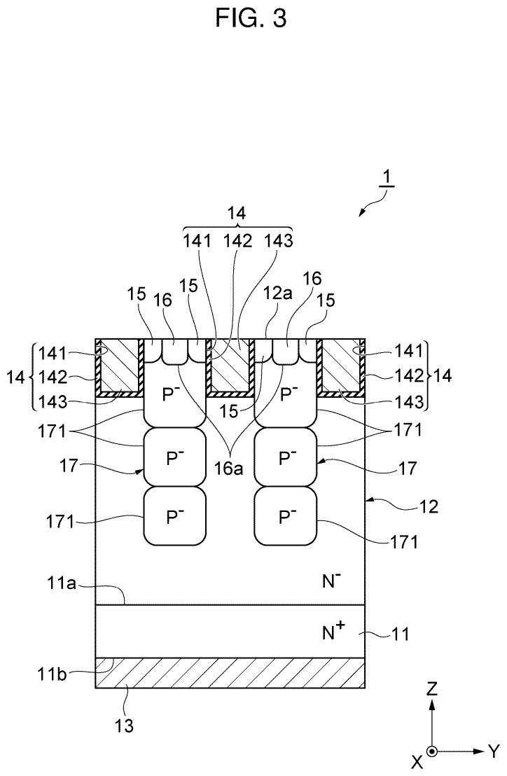

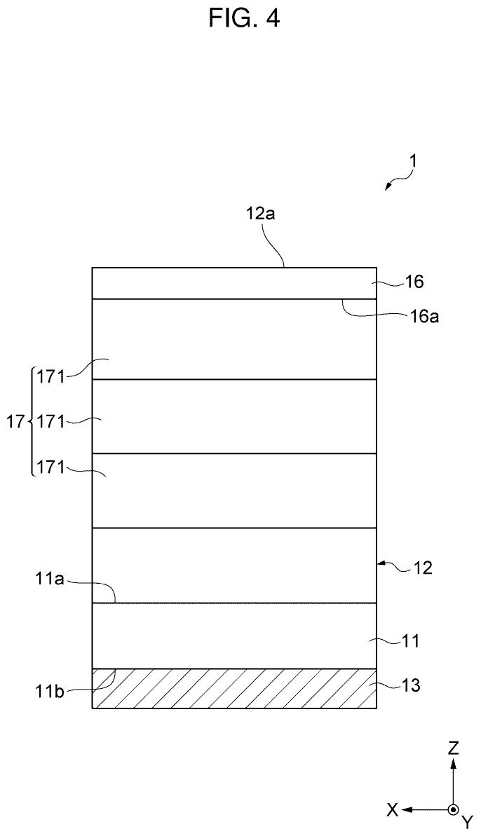

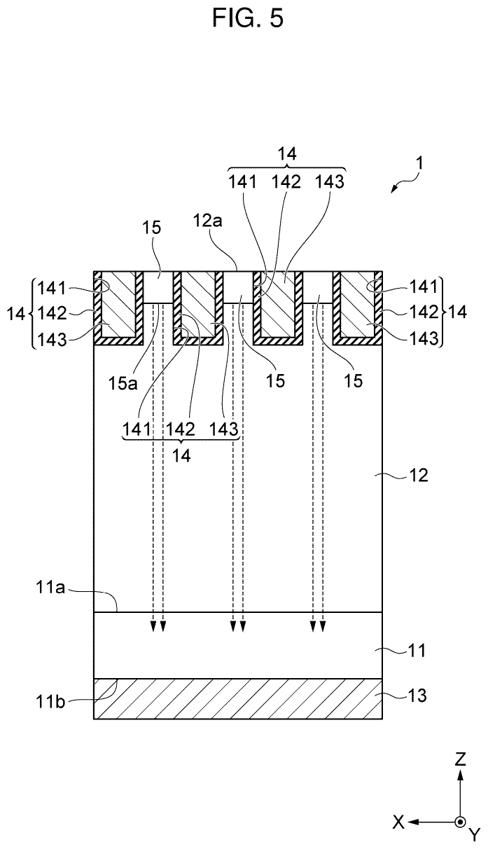

With reference to FIGS. 2 to 5, fundamental (key) structures of the semiconductor device 1 will be explained. FIG. 2 is a diagram illustrating the internal structure of the semiconductor device 1. FIG. 2 is an enlarged view of the region A shown in FIG. 1, and a diagram showing an epitaxial layer (semiconductor layer) 12 described later, viewed from above a primary surface 12a. The region A is part of the active region 2. FIG. 3 is a schematic view illustrating an example of the cross-sectional structure along the line III-III of FIG. 2. FIG. 4 is a schematic view illustrating an example of the cross-sectional structure along the line IV-IV of FIG. 2. FIG. 5 is a schematic view illustrating an example of the cross-sectional structure along the line V-V of FIG. 2. In FIGS. 3 to 5, a rear electrode 13 is illustrated as well.

In the description below, the x-axis direction, y-axis direction, and z-axis direction illustrated in FIGS. 1 to 5 are sometimes used. The z-axis direction corresponds to the direction in which the semiconductor substrate 11 and the epitaxial layer 12 are layered, the thickness direction of the epitaxial layer 12, and the thickness direction of the semiconductor substrate 11. The x-axis direction and the y-axis direction intersect with the z-axis direction. The x-axis direction and the y-axis direction intersect with each other.

The semiconductor device 1 includes the semiconductor substrate 11, and a semiconductor layer formed on a first surface 11a of the semiconductor substrate 11. The semiconductor layer may be an epitaxial layer formed by the epitaxy process. Explained below is an embodiment where the semiconductor layer formed on the semiconductor substrate 11 is the epitaxial layer 12.

The conductivity type of the semiconductor substrate 11 and the epitaxial layer 12 is N-type, which is the first conductivity type. Specifically, the semiconductor substrate 11 is N+. The impurity concentration of the semiconductor substrate 11 is 1×10¹⁸ cm⁻³ or greater but not exceeding 1×10²¹ cm⁻³, for example. The epitaxial layer 12 is N−, which has a lower impurity concentration than that of the semiconductor substrate 11. The impurity concentration of the epitaxial layer 12 is 1×10¹⁵ cm⁻³ or greater but not exceeding 1×10¹⁷ cm⁻³, for example.

The thickness of the semiconductor substrate 11 is 30 μm or greater but not exceeding 400 μm, for example. The thickness of the epitaxial layer 12 is 3 μm or greater but not exceeding 100 μm, for example.

As illustrated in FIG. 2, the epitaxial layer 12 has a plurality of trench gates 14 formed therein. The plurality of trench gates 14 may be formed anywhere as long as they are in the active region 2 (see FIG. 1). The plurality of trench gates 14 are formed at certain intervals along the first direction and the second direction that intersect with each other when viewed from the thickness direction of the epitaxial layer 12.

In this embodiment, the thickness direction of the epitaxial layer 12, the first direction, and the second direction intersect with each other unless otherwise noted. Specifically, the thickness direction of the epitaxial layer 12 corresponds to the z-axis direction, the first direction corresponds to the x-axis direction, and the second direction corresponds to the y-axis direction. Thus, the thickness direction of the epitaxial layer 12, the first direction and the second direction may also be referred to the z-axis direction, x-axis direction, and y-axis direction, respectively.

An interval d1 between two adjacent trench gates 14 of the plurality of trench gates 14 arranged along the x-axis direction (first direction) is 0.1 μm or greater but not exceeding 0.6 μm, for example. The interval d1 may be the length between two adjacent trench gates 14 on an imaginary line that runs through the center of each of the plurality of trench gates 14 arranged along the x-axis direction. The plurality of trench gates 14 arranged along the x-axis direction may be disposed at even intervals.

An interval d2 between two adjacent trench gates 14 of the plurality of trench gates 14 arranged along the y-axis direction (second direction) is 0.4 μm or greater but not exceeding 2 μm, for example. The interval d2 may be the length between two adjacent trench gates 14 on an imaginary line that runs through the center of each of the plurality of trench gates 14 arranged along the y-axis direction. The plurality of trench gates 14 arranged along the y-axis direction may be disposed at even intervals.

The center of a trench gate 14 means the center of the trench gate 14 viewed from the z-axis direction. The interval d1 may be shorter than the interval d2.

The shape of the trench gate 14, viewed from the z-axis direction, may be a quadrilateral (such as rectangle, square, and parallelogram) as illustrated in FIG. 2, a polygon (such as octagon or hexagon), or a circular shape (including an oval shape).

The trench gate 14 has a trench 141, a gate insulating film 142, and a gate electrode 143.

The trench 141 extends from the primary surface 12a of the epitaxial layer 12 toward the semiconductor substrate 11. The primary surface 12a is a side of the epitaxial layer 12 opposite from the semiconductor substrate 11. The length of the trench 141 in the z-axis direction is shorter than the thickness of the epitaxial layer 12. Thus, the trench 141 does not reach the semiconductor substrate 11. The length of the trench 141 in the z-axis direction corresponds to the depth of the trench gate 14. The trench 141 is formed by etching, for example. The length of the trench 141 in the z-axis direction is 0.6 μm or greater but not exceeding 3 μm, for example.

Inside the trench 141, the gate insulating film 142 is formed. The gate insulating film 142 is formed of silicon oxide and the like, for example. The gate insulating film 142 may be formed by any method that is suitable for the material of the gate insulating film 142. The gate insulating film 142 can be formed by thermal oxidation process, CVD method, and a combination thereof, for example. The thickness of the gate insulating film 142 may be 50 Å or greater but not exceeding 1000 Å (5 nm or greater but not exceeding 100 nm), for example.

The gate electrode 143 is embedded in the trench 141. Specifically, the gate electrode 143 is embedded in the trench 141 having the gate insulating film 142 formed on the inner surface thereof. The gate electrode 143 may be formed of a P-type semiconductor. Specifically, the gate electrode 143 may be formed of a P+ semiconductor. In this case, the impurity concentration of the gate electrode 143 is 1×10¹⁸ cm⁻³ or greater but not exceeding 1×10²¹ cm⁻³, for example. The gate electrode 143 may be formed of P+ polysilicon. The gate electrode 143 is formed by the CVD method and the like, for example.

As illustrated in FIG. 2, the semiconductor device 1 has source regions 15 and contact regions 16 on the primary surface 12a of the epitaxial layer 12. In FIG. 2, the source regions 15 are indicated with hatching. The contact regions 16 are provided to electrically connect column regions 17, which will be described later, to the source pad 4. In one embodiment, the contact region 16 functions as a back-gate contact region. Thus, in the descriptions below, the contact region 16 is referred to as the back-gate contact region 16 unless otherwise noted.

The source region 15 is in contact with the trench gate 14 (trench 141, specifically). The source region 15 is an N-type region. Specifically, the source region 15 is an N+ region. The impurity concentration of the source region 15 is 1×10¹⁸ cm⁻³ or greater but not exceeding 1×10²¹ cm⁻³, for example. The depth of the source region 15 may be smaller than the depth of the trench gate 14. The depth of the source region 15 is 0.1 μm or greater but not exceeding 0.6 μm, for example.

The source region 15 surrounds each trench gate 14. In this embodiment, a source region 15 that surrounds one of two trench gates 14 adjacent to each other along the x-axis direction is in contact with a source region 15 that surrounds the other of those two trench gates 14. That is, when viewed from the z-axis direction, the source region 15 fills the gap between the two trench gates 14 adjacent to each other along the x-axis direction.

A source region 15 that surrounds one of two trench gates 14 adjacent to each other along the y-axis direction is not in contact with a source region 15 that surrounds the other of those two trench gates 14.

The back-gate contact region 16 is formed between a source region 15 that surrounds one of two trench gates 14 adjacent to each other along the y-axis direction and a source region 15 that surrounds the other of those two trench gates 14 on the primary surface 12a of the epitaxial layer 12. As illustrated in FIGS. 2 and 4, the back-gate contact region 16 extends in the x-axis direction when viewed from the z-axis direction. The back-gate contact region 16 may extend from one end of the active region 2 to the other end thereof in the x-axis direction when viewed from the z-axis direction. The back-gate contact region 16 is P-type, which is the second conductivity type. In this embodiment, the back-gate contact region 16 is P+. The impurity concentration of the back-gate contact region 16 is 1×10¹⁸ cm⁻³ or greater but not exceeding 1×10²¹ cm⁻³, for example. The length of the back-gate contact region 16 in the z-axis direction is 0.1 μm or greater but not exceeding 1.0 μm, for example. The depth of the back-gate contact region 16 may be the same as the depth of the source region 15. The length of the back-gate contact region 16 in the y-axis direction is 0.2 μm or greater but not exceeding 2 μm, for example.

As illustrated in FIGS. 3 and 4, the semiconductor device 1 has a column region 17 that extends from a lower end 16a of the back-gate contact region 16 toward the semiconductor substrate 11. The lower end 16a is one end of the back-gate contact region 16 that is closer to the semiconductor substrate 11. When viewed from the z-axis direction, the column region 17 extends in the x-axis direction, similar to the back-gate contact region 16. The length of the column region 17 in the z-axis direction is shorter than the length between the lower end 16a and the semiconductor substrate 11. The lower end 17a of the column region 17 is not in contact with the semiconductor substrate 11. The length of the column region 17 is 1 μm or greater but not exceeding 20 μm, for example. The column region 17 is a P-type region. Specifically, the column region 17 is P−, which has a lower impurity concentration than that of the back-gate contact region 16. The impurity concentration of the column region 17 is 1×10¹⁵ cm⁻³ or greater but not exceeding 1×10¹⁷ cm⁻³, for example.

In one embodiment, the column region 17 may have a plurality of column sections 171 stacked along the z-axis direction as illustrated in FIGS. 3 and 4. In the embodiment illustrated in FIGS. 3 and 4, respective column sections 171 adjacent to each other along the z-axis direction are in contact with each other. Alternatively, column sections 171 adjacent to each other along the z-axis direction may be separated from each other. If adjacent column sections 171 are separated from each other, the space therebetween is 0.5 μm or greater but not exceeding 2 μm, for example. The number of the column sections 171 may be limited to three as illustrated in FIGS. 3 and 4, or may be two, or four or more. The column region 17 having a plurality of column sections 171 is formed by multi-epitaxy where the P-type impurity injection process and the epitaxial growth process for forming the column region 17 are alternately performed.

The length of the column region 17 in the y-axis direction may approximately the same as the interval d2 between two trench gates 14 adjacent to each other along the y-axis direction. The column regions 17 are arranged at certain intervals along the y-axis direction. The interval is 5 μm or greater but not exceeding 20 μm, for example. The column region 17 may or may not be in contact with the source region 15.

By having the column regions 17 arranged at certain intervals along the y-axis direction in the epitaxial layer 12, the semiconductor device 1 has the super-junction structure.

The positional relationships between the plurality of trench gates 14, source regions 15, back-gate contact regions 16, and column regions 17 may be represented as follows, for example.

On the primary surface 12a of the epitaxial layer 12 in the semiconductor device 1, a plurality of source regions 15 are formed at certain intervals along the y-axis direction when viewed from the z-axis direction. Each of the source regions 15 extends in the x-axis direction. Each of the source regions 15 has a plurality of trench gates 14 formed at certain intervals along the x-axis direction. The length of each trench gate 14 in the y-axis direction is shorter than the length of the source region 15 in the y-axis direction. Thus, each trench gate 14 formed in the source region 15 is in contact with the source region 15 and surrounded by the source region 15. On the primary surface 12a, back-gate contact regions 16 are each formed between two source regions 15 adjacent to each other along the y-axis direction. The back-gate contact region 16 is in contact with the source region 15 and extends in the x-axis direction. In the epitaxial layer 12, the column region 17 is formed to extend from the lower end 16a of the back-gate contact region 16 toward the semiconductor substrate 11.

As illustrated in FIGS. 3 to 5, in the semiconductor device 1, a rear electrode 13 is formed on the second surface 11b of the semiconductor substrate 11. The second surface 11b is the side opposite from the first surface 11a. The rear electrode 13 may be formed to cover the second surface 11b entirely. The rear electrode 13 functions as the drain electrode in the semiconductor device 1. For the rear electrode 13, an electrode having a multilayer structure (Ti/Ni/Au/Ag) where titanium (Ti), nickel (Ni), gold (Au) and silver (Ag) are layered in this order from the semiconductor substrate 11 may be used, for example.

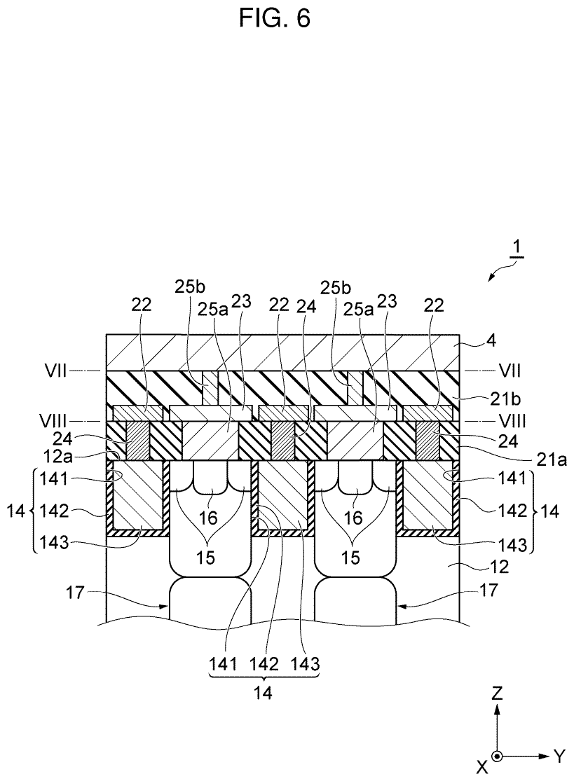

In the semiconductor device 1, the source regions 15 and the back-gate contact regions 16 are electrically connected to the source pad 4, and the gate electrodes 143 are electrically connected to the gate pad 5. With reference to FIGS. 6 to 8, an example of wiring structure between the source regions 15/back-gate contact regions 16 and the source pad 4, and between the gate electrodes 143 and the gate pad 5 will be explained. However, the structure for electrically connecting the source regions 15 and the back-gate contact regions 16 to the source pad 4, and the structure for electrically connecting the gate electrodes 143 to the gate pad 5 are not limited to the configurations described with reference to FIGS. 6 to 8.

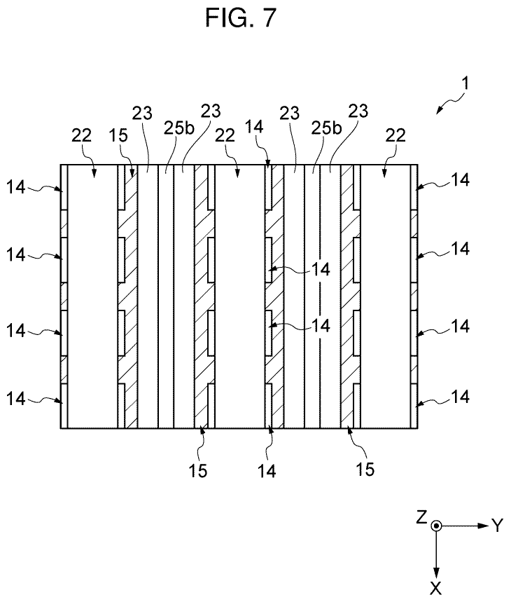

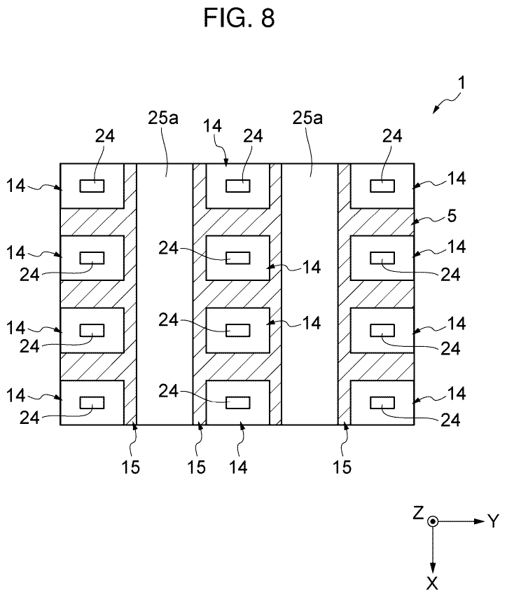

FIG. 6 is a diagram illustrating an example of the structure on the primary surface 12a in the semiconductor device 1. Similar to FIG. 3, FIG. 6 schematically shows the cross-sectional structure along the III-III line of FIG. 2. FIG. 7 is a plan view of the epitaxial layer (semiconductor layer) 12, viewed from the VII-VII line of FIG. 6. FIG. 8 is a plan view of the epitaxial layer (semiconductor layer) 12, viewed from the VIII-VIII line of FIG. 6. Similar to FIG. 2, the region illustrated in FIGS. 7 and 8 corresponds to the region A of FIG. 1. Interlayer insulating films 21a and 21b are omitted from FIGS. 7 and 8. In other words, FIGS. 7 and 8 schematically show the configuration, seen through the interlayer insulating films 21a and 21b. Similar to FIG. 2, the hatching in FIGS. 7 and 8 indicates the source regions 15.

On the primary surface 12a of the epitaxial layer 12 in the semiconductor device 1, an interlayer insulating film 21a is formed. The interlayer insulating film 21a is made of an insulating material such as silicon oxide and silicon nitride, for example.

On the interlayer insulating film 21a, a gate wire 22 is formed above the trench gate 14 (more specifically above the gate electrode 143). The gate wire 22 is a wire to electrically connect the gate pad 5 to the gate electrodes 143, also known as a gate liner. The gate wire 22 is formed of a conductive material.

The gate wire 22 is routed on the interlayer insulating film 21a such that it is electrically connected to the respective gate electrodes 143 of the plurality of trench gates 14. As illustrated in FIG. 7, for example, in the region A of FIG. 1, a plurality of gate wires 22 extending in the x-axis direction are arranged along the y-axis direction. The plurality of gate wires 22 are connected to each other on the outside of the region illustrated in FIG. 7, and are electrically connected to the gate pad 5 as well.

The gate wire 22 is electrically connected to the gate electrode 143 through a gate contact via 24 formed in the interlayer insulating film 21a (see FIGS. 6 and 8). The gate contact via 24 may be formed by filling a through hole formed in the interlayer insulating film 21a with a conductive material. As illustrated in FIG. 8, the gate contact via 24 is provided for each trench gate 14.

On the interlayer insulating film 21a, a source wire 23 is formed in a region between the trench gates 14 adjacent to each other along the y-axis direction (more specifically above the source region 15 and the back-gate contact region 16). The source wire 23 is electrically insulated from the gate wire 22. The source wire 23 is a wire that electrically connects the source region 15 and the back-gate contact region 16 to the source pad 4. In this embodiment, as illustrated in FIGS. 6 and 7, a plurality of source wires 23 extending in the x-axis direction are arranged along the y-axis direction.

The source wire 23 is electrically connected to the source region 15 and the back-gate contact region 16 through a source contact via 25a formed in the interlayer insulating film 21a (see FIGS. 6 and 8). The source contact via 25a may be formed by filling a through hole formed in the interlayer insulating film 21a with a conductive material. The source contact via 25a may be formed of the same conductive material as that used for the gate contact via 24. In this embodiment, as illustrated in FIGS. 6 and 8, a plurality of source contact vias 25a extending in the x-axis direction are arranged along the y-axis direction.

On the interlayer insulating film 21a, the interlayer insulating film 21b is formed to cover the gate wires 22 and the source wires 23. The interlayer insulating film 21b may be formed of the same material as that of the interlayer insulating film 21a. In this case, the interlayer insulating film 21a and the interlayer insulating film 21b may also be regarded as one interlayer insulating film. Space between the gate wires 22 and the source wires 23 is also filled by the interlayer insulating film 21b. This further ensures the gate wires 22 and the source wires 23 are electrically insulated from each other.

On the interlayer insulating film 21b, the source pad 4 (see FIG. 1) and the gate pad 5 (not shown in FIGS. 7 and 8) are formed.

The source pad 4 is electrically connected to the source wires 23 through source contact vias 25b formed in the interlayer insulating film 21b. In this embodiment, as illustrated in FIGS. 6 and 7, a plurality of source contact vias 25b extending in the x-axis direction are arranged along the y-axis direction. As described above, the source wires 23 are electrically connected to the source regions 15 and the back-gate contact regions 16 through the source contact vias 25a. Thus, the source pad 4 is electrically connected to the source regions 15 and the back-gate contact regions 16 through the source contact vias 25b, the source wires 23, and the source contact vias 25a.

The gate pad 5 is electrically connected to the gate wires 22 through gate contact vias (not shown) formed in the interlayer insulating film 21b. As described above, the gate wires 22 are electrically connected to the gate electrodes 143 through the gate contact vias 24. Thus, the gate pad 5 is electrically connected to the gate electrodes 143 through the gate contact vias (not shown) formed in the interlayer insulating film 21b, the gate wires 22 and the gate contact vias 24.

The semiconductor device 1 is manufactured in the following manner, for example.

On the first surface 11a of the semiconductor substrate 11, the epitaxial layer 12 having a plurality of column regions 17 arranged at certain intervals along the y-axis direction and extending along the x-axis direction is formed by epitaxy (semiconductor layer forming process). Specifically, the epitaxial layer 12 is formed by performing epitaxy while ion-injecting an N-type impurity. In the step of forming the column regions 17 during the process of forming the epitaxial layer 12, multi-epitaxy is conducted where the P-type impurity injection process and the epitaxial growth process for forming the column regions 17 are alternately performed. In this way, the epitaxial layer 12 including the column regions 17 is formed. The column regions 17 formed in this process each have a plurality of column sections 171 stacked along the z-axis direction. The column regions 17 are formed not to be in contact with the primary surface 12a of the epitaxial layer 12.

Next, the back-gate contact region forming process to form the back-gate contact regions 16 (contact region forming process), the source region forming process to form the source regions 15, and the trench gate forming process to form the trench gates 14 are performed. The back-gate contact region forming process, the source region forming process and the trench gate forming process may take place in any order. Here, as an example, the back-gate contact region forming process, the source region forming process and the trench gate forming process are performed in this order.

In the back-gate contact region forming process, P-type impurity is selectively injected from the primary surface 12a to the areas where the back-gate contact regions 16 are to be formed, thereby forming the back-gate contact regions 16 that respectively correspond to the plurality of column regions 17 and that extend along the x-axis direction. The back-gate contact regions 16 are formed to be in contact with the column regions 17. Because the epitaxial layer 12 has a plurality of column regions 17 arranged along the y-axis direction, the back-gate contact region forming process results in a plurality of back-gate contact regions 16 arranged along the y-axis direction.

In the source region forming process, N-type impurity is selectively injected from the primary surface 12a to each area between two adjacent back-gate contact regions 16 among the plurality of back-gate contact regions 16 arranged along the y-axis direction, thereby forming the source regions 15 that extend in the x-axis direction. This way, a plurality of source regions 15 extending in the x-axis direction are formed along the y-axis direction.

In the trench gate forming process, trench gates 14 are formed at certain intervals along the x-axis direction in each of the plurality of source regions 15 arranged along the y-axis direction. The trench gates 14 are formed in the following manner, for example.

On the primary surface 12a of the epitaxial layer 12, trenches 141 are formed by etching, for example. Then, the gate insulating film 142 is formed inside each trench 141. The gate insulating film 142 is formed by performing thermal oxidation on the inner surface of the respective trenches 141. After forming the gate insulating film 142, each trench 141 is filled with the gate electrode 143. The gate electrode 143 is formed by the CVD method and the like, for example.

The manufacturing method of the semiconductor device 1 may include a rear electrode forming process. In the rear electrode forming process, the rear electrode 13 is formed on the second surface 11b of the semiconductor substrate 11 by the CVD method or the like.

After performing the rear electrode forming process, an upper wire structure forming process and a pad forming process may be performed.

In the upper wire structure forming process, a structure to electrically connect the source pad 4 and the source regions 15/back-gate contact regions 16, and to electrically connect the gate pad 5 and the gate electrodes 143 is formed on the primary surface 12a as the upper wire structure. Explained here is the process to form the wire structure explained with reference to FIGS. 7 to 8.

The interlayer insulating film 21a is formed on the primary surface 12a by the CVD method or the like. Next, the gate contact vias 24 and the source contact vias 25a explained with reference to FIGS. 7 to 8 are formed in the interlayer insulating film 21a. The gate contact vias 24 and the source contact vias 25a may be formed by forming corresponding through-holes in the interlayer insulating film 21a, and filling those through-holes with a conductive material.

Next, on the interlayer insulating film 21a, the gate wires 22 are formed to be electrically connected to the gate contact vias 24, and the source wires 23 are formed to be electrically connected to the source contact vias 25a. The gate wires 22 and the source wires 23 may be formed by forming a conductive layer on the interlayer insulating film 21a using a conductive material for the gate wires 22 and the source wires 23, and then patterning the conductive layer into the pattern of the gate wires 22 and the source wires 23. Alternatively, the gate wires 22 and the source wires 23 may be formed by forming a resist layer having an opening that corresponds to the pattern of the gate wires 22 and the source wires 23 on the interlayer insulating film 21a, filling the opening with a conductive layer, and then removing the resist layer.

After forming the gate wires 22 and the source wires 23 in the manner described above, the interlayer insulating film 21b is formed on the interlayer insulating film 21a by the CVD method or the like to cover the gate wires 22 and the source wires 23.

After forming the interlayer insulating film 21b, the source contact vias 25b (see FIG. 7) for electrically connecting the source pad 4 and the source wires 23, and the gate contact vias (not shown) for electrically connecting the gate pad 5 and the gate wires 22 are formed in the interlayer insulating film 21b. The gate contact vias for electrically connecting the gate pad 5 and the gate wires 22 and the source contact vias 25b may be formed in the manner similar to the source contact vias 25a and the gate contact vias 24 formed in the interlayer insulating film 21a.

In the pad forming process, the source pad 4 and the gate pad 5 are formed on the interlayer insulating film 21b. The source pad 4 is formed to be electrically connected to the source contact vias 25b, and the gate pad 5 is formed to be electrically connected to the gate contact vias 24 formed in the interlayer insulating film 21a.

The semiconductor device 1 is manufactured through the processes described above. In each process, a masking process may be performed to form components (such as the source regions 15 and the back-gate contact regions 16) in certain regions selectively, for example.

In the semiconductor device 1, a plurality of column regions 17 are arranged along the y-axis direction, and the super-junction structure is formed between the plurality of column regions 17 and the epitaxial layer 12. Because the semiconductor device 1 has the super-junction structure, it is easier to ensure voltage endurance even when the impurity concentration in the epitaxial layer 12 is made higher. This makes it possible to reduce the resistance from the epitaxial layer 12, allowing for a lower ON resistance.

Further, the semiconductor device 1 has the trench gates 14, and a plurality of trench gates 14 are arranged at certain intervals along the first direction and the second direction. In other words, the plurality of trench gates 14 are arranged two-dimensionally. In this configuration, it is possible to reduce the distance between two adjacent trench gates 14 when viewed from the z-axis direction. This makes it possible to increase the channel density per unit area, which can further reduce the ON resistance.

In the semiconductor device 1, the source region 15 is formed to be in contact with the trench gates 14 and surrounds the trench gates 14. The lower end 15a (see FIG. 5) of each source region 15 located between trench gates 14 adjacent to each other along the x-axis direction is in contact with the epitaxial layer 12. The lower end 15a is one end of the source region 15 that is closer to the semiconductor substrate 11. In this configuration, when the semiconductor device 1 is driven (turned on), electrons flow from the source region 15 between trench gates 14 adjacent to each other along the x-axis direction toward the semiconductor substrate 11 as indicated with the broken line arrow in FIG. 5. That is, in the epitaxial layer 12, a part between the semiconductor substrate 11 and each source region 15, which is located between trench gates 14 adjacent to each other along the x-axis direction, functions as the channel region. This configuration makes it possible to further reduce the ON resistance. This will be explained in further detail below.

In MOSFETs, source regions, which correspond to the source regions 15, are generally formed in the P-type body diffusion region (P-type diffusion region). In this configuration, the source regions are surrounded by the P-type body diffusion region, which also functions as the channel. Because the P-type body diffusion region requires a high impurity concentration (1×10¹⁶ cm⁻³ or greater but not exceeding 1×10¹⁷ cm⁻³), the electron mobility is reduced. In particular, if SiC that has a greater degree of surface diffusion is used for the semiconductor material, the reduction in channel mobility would cause the ON resistance to increase.

On the other hand, the semiconductor device 1 of Embodiment 1 employs a configuration that does not require the P-type body diffusion region. That is, in the semiconductor device 1, the source region 15 is formed to be in contact with the trench gates 14 and surround the trench gates 14. Even though the semiconductor device 1 does not have the P-type body diffusion region, it is still possible to generate a depletion layer near the trench gate 14 by adjusting the gate voltage Vgs (voltage between the gate and the source) applied to the gate electrode 143, and during the ON state, the depletion layer can be erased to make electrons flow (or make electric current flow) from the source region 15 between trench gates 14 adjacent to each other along the x-axis direction toward the semiconductor substrate 11. The semiconductor device 1 without the P-type body diffusion region does not have a resistance from the electrons flowing through the P-type body diffusion region. Furthermore, in the semiconductor device 1, electrons (electric current) flow through the epitaxial layer 12 that has a lower impurity concentration than that of the P-type body diffusion region and that is closer to the bulk, which makes it possible to reduce the channel resistance. As a result, the ON resistance can be reduced even further.

In the configuration where the gate electrode 143 is formed of a P+ semiconductor, it is possible to form a depletion layer near the trench gates 14 even without the P-type body diffusion layer because the area near the trench gates 14 is depleted when the gate voltage Vgs is not applied to the gate electrode 143 (Vgs=0) due to the working function difference. That is, a normally off MOSFET can be achieved. When a positive voltage is applied to the gate electrode 143 as the gate voltage Vgs, the depletion layer disappears, electric current flows, and the semiconductor device 1 is turned on. In the semiconductor device 1 in the ON state, electric current flows through the epitaxial layer 12 that has a lower impurity concentration than that of the P-type body diffusion region and that is closer to the bulk, instead of an inverted channel layer, which makes it possible to reduce the channel resistance. As a result, the ON resistance can be reduced even further.

When the interval between trench gates 14 adjacent to each other along the x-axis direction is 0.1 μm or greater but not exceeding 0.6 μm, it is easier for the depletion layer to be formed near the trench gates 14, which creates the OFF state.

When a gap between trench gates 14 adjacent to each other along the x-axis direction is filled with the source region 15, a larger channel can be formed, which makes it easier for electric current to flow through.

An MOSFET using SiC as the semiconductor material has relatively large surface diffusion, which could lead to greater channel resistance and higher ON resistance. The semiconductor device 1 that can reduce the channel resistance becomes even more effective for a semiconductor device that uses SiC.

The semiconductor device 1 may be installed in a power module used for an inverter circuit that constitutes a driving circuit for driving an electric motor used for a power source of electric vehicles (including hybrid vehicles), trains, industrial robots and the like, for example. The semiconductor device 1 may also be installed in a power module used for an inverter circuit that converts electricity generated by a solar panel, wind power generator and other generator (non-utility generator in particular) to match electricity from commercial power supply.

### Embodiment 2

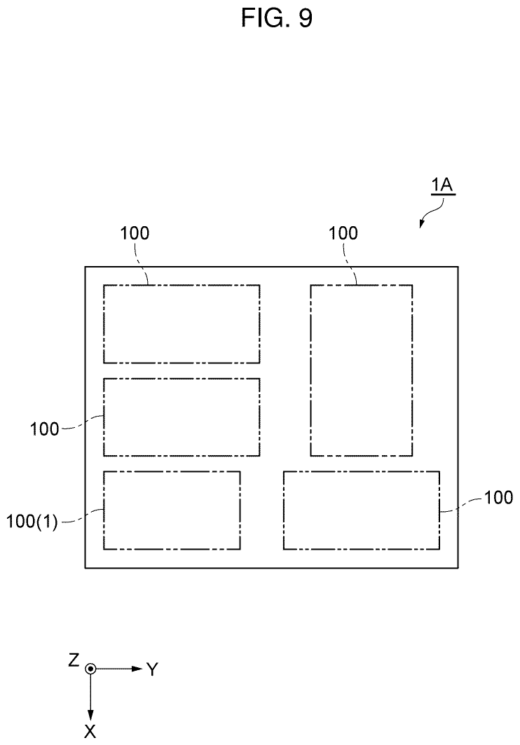

FIG. 9 is a plan view of a semiconductor device 1A of Embodiment 2. The semiconductor device 1A is shaped like a chip, for example, and more specifically, shaped like a cuboid or cube. The semiconductor device 1A is an integrated semiconductor device including a plurality of device regions 100. The device regions 100 can take any number, any arrangement and any shape, and are not limited to specific number, arrangement or shape.

Each of the plurality of device regions 100 includes function devices formed inside and outside of the semiconductor device 1A. One of those function devices is the semiconductor switching device. The semiconductor device 1A contains, as the semiconductor switching device, the semiconductor device 1 described in Embodiment 1 in at least one of the plurality of device regions 100. In other words, at least one of the plurality of device regions 100 has the configuration of the semiconductor device 1 according to Embodiment 1.

The semiconductor device 1A may include a digital semiconductor device or analog semiconductor device as an example of the function devices. Those digital and analog semiconductor devices may include MOS transistors, bipolar transistors, and the like. The function devices mentioned above may include at least one of a semiconductor rectifier device and a receptor device, in addition to the semiconductor switching device, for example. The function devices in the semiconductor device 1A may also include a circuit network that combines at least two of the semiconductor switching device, semiconductor rectifier device and receptor device.

The semiconductor device 1A may contain, as the semiconductor switching device, other types of switching device than the semiconductor device 1 described in Embodiment 1, such as an IGBT (insulated gate bipolar junction transistor). The semiconductor rectifier device may include at least one of a pn junction diode, a pin junction diode, a Zener diode, a Schottky barrier diode, and a fast recovery diode. The receptor device may include at least one of a resistance, capacitor, inductor and fuse.

In the semiconductor device 1A, the semiconductor substrate 11 and the epitaxial layer 12 described in Embodiment 1 may be a semiconductor substrate 11 and an epitaxial layer 12 that are shared with other device regions 100. In the semiconductor device 1A, the rear electrode 13 of the semiconductor device 1 described in Embodiment 1 may be a common electrode shared with other device regions 100. However, each area of the rear electrode corresponding to each device region 100 functions as an electrode for that device region 100.

Of the plurality of device regions 100 in the semiconductor device 1A, at least one device region has the same configuration as that of the semiconductor device 1 according to Embodiment 1. Thus, the semiconductor device 1A has the same effects as those of the semiconductor device 1.

The semiconductor device 1A may also be installed in a power module used for an inverter circuit that constitutes a driving circuit for driving an electric motor used for a power source of electric vehicles (including hybrid vehicles), trains, industrial robots and the like. The semiconductor device 1A may also be installed in a power module used for an inverter circuit that converts electricity generated by a solar panel, wind power generator and other generator (non-utility generator in particular) to match electricity from commercial power supply.

### Modification Example 1

Each embodiment above illustrated the case where the first conductivity type was N and the second conductivity type was P. However, the first conductivity type may be P, and the second conductivity type may be N. In other words, it is also possible to employ a configuration in which the conductivity types of semiconductor elements of the semiconductor devices 1 and 1A are switched. For example, in the semiconductor devices 1 and 1A, the P-type components may be N-type components and the N-type components may be P-type components.

### Modification Example 2

The material of the gate electrode 143 is not limited to a P+ semiconductor. The gate electrode 143 may alternatively be formed of N+ semiconductor (such as polysilicon), for example. In this case, the depletion layer can be formed near the trench gate 14 by applying a negative gate voltage Vgs to the gate electrode 143, for example.

### Modification Example 3

The source region 15 does not need to completely fill the gap between two trench gates 14 adjacent to each other along the x-axis direction. That is, there may be a gap between the source region 15 that surrounds one of two adjacent trench gates 14 and the source region 15 that surrounds the other of those two trench gates 14.

### Modification Example 4

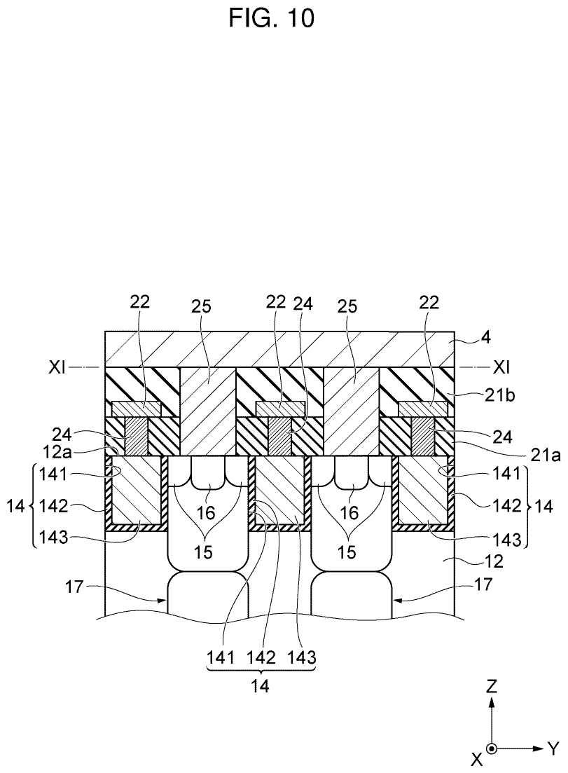

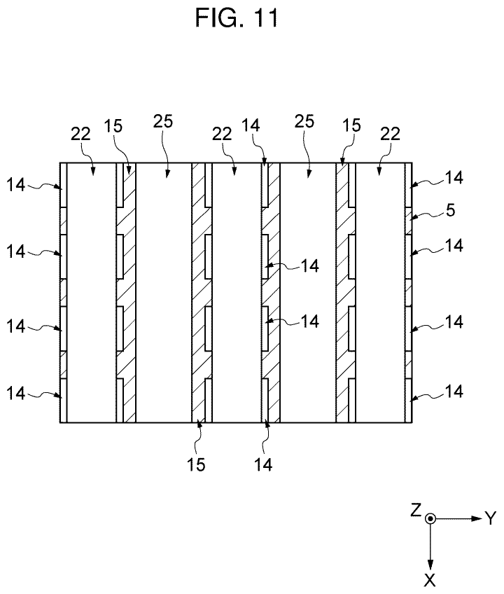

The structure to electrically connect the source region 15 and the back-gate contact region 16 to the source pad 4 may be configured in a manner illustrated in FIGS. 10 and 11.

FIG. 10 is a diagram illustrating another example of the structure on the primary surface 12a in the semiconductor device 1. Similar to FIG. 3, FIG. 10 schematically shows the cross-sectional structure along the III-III line of FIG. 2. FIG. 11 is a plan view of the epitaxial layer (semiconductor layer) 12, viewed from the XI-XI line of FIG. 10. The interlayer insulating films 21a and 21b are omitted from FIGS. 10 and 11, similar to FIGS. 7 and 8. In other words, FIGS. 10 and 11 schematically show the configuration, seen through the interlayer insulating films 21a and 21b. Similar to FIG. 2, the hatching in FIG. 11 indicates the source regions 15.

The wiring structure illustrated in FIGS. 10 and 11 is the same as the wiring structure illustrated using FIGS. 7 and 8 except that the source pad 4 is electrically connected to the source regions 15 and the back-gate contact regions 16 through the source contact vias 25, instead of using the source wires 23.

The source contact via 25 is formed through the interlayer insulating film 21a and the interlayer insulating film 21b between the primary surface 12a and the source pad 4. The source contact via 25 corresponds to a via obtained by extending the source contact via 25a illustrated in FIG. 7 to reach the source pad 4. The wiring structure between the gate electrodes 143 and the gate pad 5 may be the same as that illustrated using FIGS. 7 and 8.

The wiring structure illustrated in FIGS. 10 and 11 may be formed in the same manner as the upper wiring structure forming process described in Embodiment 1 except that a part of the source contact via 25 that is located inside the interlayer insulating film 21a is formed in the same manner as the source contact via 25a formed in the interlayer insulating film 21a (see FIG. 7), that the source wires 23 are not formed, and that a part of the source contact via 25 that is located inside the interlayer insulating film 21b is formed in the same manner as the source contact via 25b (see FIG. 7).

The source contact via 25 may be formed to run through the interlayer insulating films 21a and 21b after the interlayer insulating films 21a and 21b are formed.

### Modification Example 5

The manufacturing method of the semiconductor device 1 is not limited to the example illustrated above. For example, the manufacturing method of the semiconductor device may include: a semiconductor layer forming process to form the semiconductor layer 12 of the first conductivity type having the primary surface 12a on the semiconductor substrate 11 of the first conductivity type; a column region forming process to form the column region 17 of the second conductivity type in the semiconductor layer 12 such that the primary surface 12a is not in contact with the column region 17; a trench gate forming process to form the trench 141, the gate insulating film 142 and the gate electrode 143 in the semiconductor layer 12 in which the column region 17 is formed; a source region forming process to form the source region 15 of the first conductivity type on the primary surface 12a of the semiconductor layer 12 in which the column region 17 is formed; and a back-gate contact region forming process to form the back-gate contact region 16 of the second conductivity type on the primary surface 12a of the semiconductor layer 12 in which the column region 17 is formed such that the back-gate contact region 16 is in contact with the column region 17. In the column region forming process of the manufacturing method described in Modification Example 5, the column region 17 is formed to extend in the first direction, out of the first direction (x-axis direction) and the second direction (y-axis direction) that intersect each other when viewed from the thickness direction (z-axis direction) of the semiconductor layer 12, and a plurality of column regions 17 are formed at certain intervals along the second direction. In the back-gate contact region forming process of the manufacturing method of Modification Example 5, a back-gate contact region 16 is formed for each of the plurality of column regions 17, or in other words, a plurality of back-gate contact regions 16 are formed. In the trench gate forming process of the manufacturing method of Modification Example 5, a plurality of trench gates 14 are formed at certain intervals along the first direction, each between two column regions adjacent to each other when viewed from thickness direction, out of the plurality of column regions 17. In the source region forming process of the manufacturing method of Modification Example 5, the source region 15 is formed to be in contact with the trench gate 14 and surround the trench gate 14 when viewed from the thickness direction, or to be in contact with a trench gate forming region in which the trench gate 14 is to be formed and surround the trench gate forming region when viewed from the thickness direction.

As understood from the descriptions above, the semiconductor device according to this enclosure can reduce ON resistance.

Multiple illustrative embodiments have been discussed above, but the present disclosure is not limited to those illustrative embodiments, and may be abridged, replaced or modified in various manners. In the various embodiments described above (including the modification examples), one or more components of one embodiment may be combined with one or more components of another embodiment. It is understood from the descriptions above that the various embodiments of this disclosure are merely illustrative in all aspects, and various modifications may be made without departing from the scope and purpose of the present disclosure. Thus, the various embodiments disclosed in the present specification are not intended to limit the present disclosure, and the true scope and purpose thereof are represented by the claims.

Below, representative examples extracted from the present specification and figures will be discussed.

[A1] (FIGS. 2 to 5)

A semiconductor device (1), including:
a semiconductor substrate (11) of a first conductivity type; and
a semiconductor layer (12) of the first conductivity type that is located on the semiconductor substrate and that has a primary surface (12a) on a side opposite to the semiconductor substrate;
wherein the semiconductor layer includes:
a trench gate (14) having a trench (141) that extends from the primary surface toward the semiconductor substrate, a gate insulating film (142) formed on an inner surface of the trench, and a gate electrode (143) that fills up the trench via the gate insulating film;
a source region (15) of the first conductivity type formed on the primary surface;
a contact region (16) of a second conductivity type formed on the primary surface;
   a column region (17) of the second conductivity type;
   wherein, in the semiconductor layer, a plurality of trench gates are formed at certain intervals along a first direction (X) and a second direction (Y), respectively, that intersect with each other when viewed from a thickness direction (Z) of the semiconductor layer,
wherein the source region is in contact with the trench gate and surrounds the trench gate when viewed from the thickness direction,
wherein the contact region is located between two source regions that are adjacent to each other along the second direction; and
wherein the column region extends toward the semiconductor substrate from one end (16a) of the contact region that is closer to the semiconductor substrate.

[A2]

The semiconductor device according to [A1], wherein the gate electrode is made of a semiconductor of the second conductivity type.

[A3]

The semiconductor device according to [A1] or [A2], wherein a gap between the trench gates adjacent to each other along the first direction is filled with the source region.

[A4]

The semiconductor device according to any one of [A1] to [A3], wherein, in the source region located between the trench gates adjacent to each other along the first direction, one end thereof that is closer to the semiconductor substrate is in contact with the semiconductor layer.

[A5]

The semiconductor device according to any one of [A1] to [A4], wherein an interval between the trench gates adjacent to each other along the first direction is 0.1 μm or greater but not exceeding 0.6 μm.

[A6]

The semiconductor device according to any one of [A1] to [A5], wherein the first direction and the second direction intersect with each other.

[B1]

A semiconductor device, including:
a semiconductor substrate (11) of a first conductivity type; and
a semiconductor layer (12) of the first conductivity type that is located on the semiconductor substrate and that has a primary surface on a side opposite to the semiconductor substrate;
wherein the semiconductor layer includes:
a trench gate (14) having a trench (141) that extends from the primary surface toward the semiconductor substrate, a gate insulating film (142) formed on an inner surface of the trench, and a gate electrode (143) that fills up the trench via the gate insulating film;
a source region (15) of the first conductivity type formed on the primary surface and extending in a first direction;
a contact region (16) of a second conductivity type formed on the primary surface and extending in the first direction;
a column region (17) of the second conductivity type that extends in the first direction,
   wherein, in the semiconductor layer, a plurality of source regions are formed at certain intervals along a second direction (Y) that intersects with the first direction (X) when viewed from a thickness direction (Z) of the semiconductor layer,
   wherein each of the source regions has the trench gates formed therein at certain intervals along the first direction when viewed from the thickness direction,
wherein the contact region is located between two source regions that are adjacent to each other along the second direction; and
wherein the column region extends toward the semiconductor substrate from one end of the contact region that is closer to the semiconductor substrate.

[C1]

A manufacturing method of a semiconductor device, including:
a semiconductor layer forming step of forming, on a semiconductor substrate (11) of a first conductivity type, a semiconductor layer (12) of the first conductivity type that has a primary surface (12a) on a side opposite to the semiconductor substrate;
a column region forming step of forming a column region of a second conductivity type on the semiconductor layer such that the primary surface and the column region are not in contact with each other,
a trench gate forming step of forming, on the semiconductor layer having the column region thereon, a trench gate (14) having a trench (141) that extends from the primary surface toward the semiconductor substrate, a gate insulating film (142) formed on an inner surface of the trench, and a gate electrode (143) that fills up the trench via the gate insulating film;
a source region forming step of forming a source region (15) of the first conductivity type on the primary surface of the semiconductor layer having the column region formed thereon;
a contact region forming step of forming a contact region (16) of the second conductivity type on the primary surface of the semiconductor layer having the column region formed thereon such that the contact region is in contact with the column region, wherein, of a first direction (X) and a second direction (Y) that intersect with each other when viewed from a thickness direction (Z) of the semiconductor layer, the column region extends in the first direction (X),
wherein, in the column region forming process, a plurality of column regions are formed at certain intervals along the second direction (Y),
wherein, in the contact region forming process, a plurality of contact regions are formed by forming the contact regions that correspond to the plurality of column regions, respectively,
wherein in the trench gate forming process, a plurality of trench gates are formed at certain intervals along the first direction (X), each between two adjacent column regions viewed from thickness direction (Z), out of the plurality of column regions,
wherein, in the source region forming process, the source region is formed to be in contact with the trench gate and surround the trench gate 14 when viewed from the thickness direction (Z), or to be in contact with a trench gate forming region in which the trench gate is to be formed and surround the trench gate forming region when viewed from the thickness direction.

[C2]

The manufacturing method of a semiconductor device according to [C1], wherein the column region forming process is performed in the semiconductor layer forming process at the same time as forming the semiconductor layer.

[C3]

The manufacturing method of a semiconductor device according to [C1] or [C2], wherein, in the source region forming process, a plurality of source regions are formed at certain intervals along the second direction (Y) by forming the source regions such that each source region extends in the first direction (X) between two contact regions adjacent to each other, out of the plurality of contact regions, when viewed from the thickness direction (Z),
wherein, in the trench gate forming process, a plurality of trench gates are formed by forming the trench gates at certain intervals along the first direction (X) in each of the plurality of source regions.

What is claimed is:

1. A semiconductor device, comprising:
a semiconductor substrate of a first conductivity type; and
a semiconductor layer of the first conductivity type disposed on the semiconductor substrate and having a primary surface on a side opposite to the semiconductor substrate,
wherein the semiconductor layer includes:
a trench gate having a trench that extends from the primary surface toward the semiconductor substrate, a gate insulating film formed on an inner surface of the trench, and a gate electrode that fills up the trench via the gate insulating film;
a source region of the first conductivity type formed on the primary surface;
a contact region of a second conductivity type formed on the primary surface;
a column region of the second conductivity type;
wherein, in the semiconductor layer, a plurality of said trench gates are formed at certain intervals along a first direction and a second direction, respectively, that intersect with each other when viewed from a thickness direction of the semiconductor layer,
wherein the source region is in contact with the trench gate and surrounds the trench gate when viewed from the thickness direction,
wherein the contact region is disposed between two source regions that are adjacent to each other along the second direction; and
wherein the column region extends toward the semiconductor substrate from one end of the contact region that is closer to the semiconductor substrate.

2. The semiconductor device according to claim 1, wherein the gate electrode is made of a semiconductor of the second conductivity type.

3. The semiconductor device according to claim 1, wherein a gap between trench gates adjacent to each other along the first direction is filled with the source region.

4. The semiconductor device according to claim 2, wherein a gap between trench gates adjacent to each other along the first direction is filled with the source region.

5. The semiconductor device according to claim 1, wherein the source region is disposed between trench gates adjacent to each other along the first direction, and one end of the source region that is closer to the semiconductor substrate is in contact with the semiconductor layer.

6. The semiconductor device according to claim 2, wherein the source region is disposed between trench gates adjacent to each other along the first direction, and one end of the source region that is closer to the semiconductor substrate is in contact with the semiconductor layer.

7. The semiconductor device according to claim 1, wherein an interval between trench gates adjacent to each other along the first direction is 0.1 μm or greater but not exceeding 0.6 μm.
